(19) United States
(12) Patent Application Publication
(10) Pub. No.: US 2008/0157842 A1
(43) Pub. Date: Jul. 3, 2008

(54) MTCMOS Flip-Flop Circuit

(76) Inventor: MIN HWAHN KIM, Seoul (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/929,933

(22) Filed: Oct. 30, 2007

(30) Foreign Application Priority Data
Dec. 28, 2006 (KR) 10-2006-0136394

(51) Int. Cl. H03K 3/356

(52) U.S. Cl. 327/211

(57) ABSTRACT

Disclosed is a multi-threshold CMOS (MTCMOS) flip-flop circuit. The MTCMOS flip-flop circuit includes a data input unit including an inverter for receiving an input data signal, inverting the input data signal and then outputting an inverted data signal; a clock signal generator including an inverter for receiving an input clock signal and a logic gate for generating a pulsed clock for latching the inverted data signal at a rising time of the input clock signal; a data transmitting unit including a switch for receiving the data signal output from the data input unit to selectively output the inverted data signal and controlling transmission of data based on the pulsed clock; and a data latch and output unit including a feedback inverter having a feedback path used for data latch so as to receive the inverted data signal and generate an output Q.

### CROSS-REFERENCE TO RELATED APPLICATION

The present application claims the benefit under 35 U.S.C. §119 of Korean Patent Application No. 10-2006-0136394, filed Dec. 28, 2006, which is hereby incorporated by reference in its entirety.

### BACKGROUND

In the implementation of a multi-threshold CMOS (hereinafter, referred to as a MTCMOS), a high-speed low-power flip-flop circuit can be used to retain data in a sleep mode.

In a conventional MTCMOS flip-flop circuit, since switches used for data transmission in a data transmitting unit are connected in series, the speed of data being transmitted to a latch may be reduced. In addition, since the size of a MOS transistor used for serial connection should be large to properly transmit data to the latch, the size of a transistor used as a switch may become large.

In the conventional MTCMOS flip-flop circuit, an inverter at an output terminal is connected to a virtual power line of an MTCMOS, and thus an output signal is floated in a sleep mode. For this reason, when a CMOS logic is connected to an output unit, an additional NAND or NOR gate should be used to convert a signal into a logic low or logic high state such that an floating output causing a leakage current is not transmitted, and an additional control signal should be used. This may be a burden when routing an actual circuit.

In the conventional MTCMOS flip-flop circuit, an additional signal generator is necessary to generate an enable (EN) signal used to allow the circuit to be in a sleep mode, and such an EN signal must be precisely controlled. For this reason, a complicated design flow is necessary to prevent malfunction of the circuit. This results in increasing TAT (Turn Around Time) for a design and increasing design costs.

In the related MTCMOS flip-flop circuit, a leakage current is generated by a MOS transistor for a latch when the circuit is in a sleep mode. However, if the size of the MOS transistor is reduced to prevent such a leakage current, the speed of the circuit may be decreased during normal operation.

### BRIEF SUMMARY

Accordingly, embodiments of the present invention provide an MTCOMS flip-flop circuit capable of retaining data (latched signals) in a sleep mode, implementing high-speed and low-power consumption in an active mode, and minimizing a leakage current in a sleep mode.

In addition, an embodiment provides an MTCOMS flip-flop circuit, wherein an output signal is not floated in a sleep mode, but a stored value is outputted, so that a design on an MTCMOS-CMOS interface can be simplified.

An embodiment of the present invention also provides an MTCOMS flip-flop circuit capable of operating not only at a positive edge but also at a negative edge of a clock signal using gate replacement.

An embodiment of the present invention provides an MTCOMS flip-flop circuit, wherein the size of the circuit and complexity of an entire design are reduced, so that a design time can be reduced, and the circuit can easily perform a stable operation through the entire design.

According to an aspect of an embodiment, there is provided an MTCMOS flip-flop circuit, which includes: a data input unit including an inverter for receiving an input data signal, inverting the input data signal and then outputting the inverted data signal; a clock signal generator including at least one inverter for receiving an input clock signal and a logic gate for generating a pulsed clock for latching the input data signal at a rising time of the input clock signal; a data transmitting unit including a switch for receiving the inverted data signal output from the data input unit to selectively output the inverted data signal, and receiving the pulsed clock output from the clock signal generator to control transmission of data; and a data latch and output unit including a feedback inverter having a feedback path used for data latch so as to receive the inverted data input signal and generate an output Q.

According to another aspect of an embodiment, there is provided an MTCMOS flip-flop circuit, which includes: a data input unit including an inverter for receiving an input data signal, inverting the input data signal and then outputting the inverted data signal; a clock signal generator including at least one inverter for receiving an input clock signal and a logic gate for generating a pulsed clock for latching the input data signal at both a rising time and falling time of the input clock signal; a data transmitting unit including a switch for receiving the inverted data signal output from the data input unit to selectively output the inverted data signal, and receiving the pulsed clock output from the clock signal generator to control transmission of data; and a data latch and output unit including a feedback inverter having a feedback path used for data latch so as to receive the inverted data input signal and generate an output Q.

### BRIEF DESCRIPTION OF THE DRAWINGS

FIG. 1 is a circuit diagram of an MTCMOS flip-flop circuit according to an embodiment of the present invention.

FIG. 2 is a view illustrating devices used in the MTCMOS flip-flop circuit according to an embodiment of the present invention.

FIG. 3 is a signal diagram of the MTCMOS flip-flop circuit according to an embodiment of the present invention.

FIG. 4 is a circuit diagram of another example of the MTCMOS flip-flop circuit according to an embodiment of the present invention.

FIG. 5 is a circuit diagram of an MTCMOS flip-flop circuit according to an embodiment of the present invention.

FIG. 6 is a signal diagram of the MTCMOS flip-flop circuit according to an embodiment of the present invention.

### DETAILED DESCRIPTION

Hereinafter, MTCMOS flip-flop circuits according to certain embodiments of the present invention will be described with respect to the accompanying drawings.

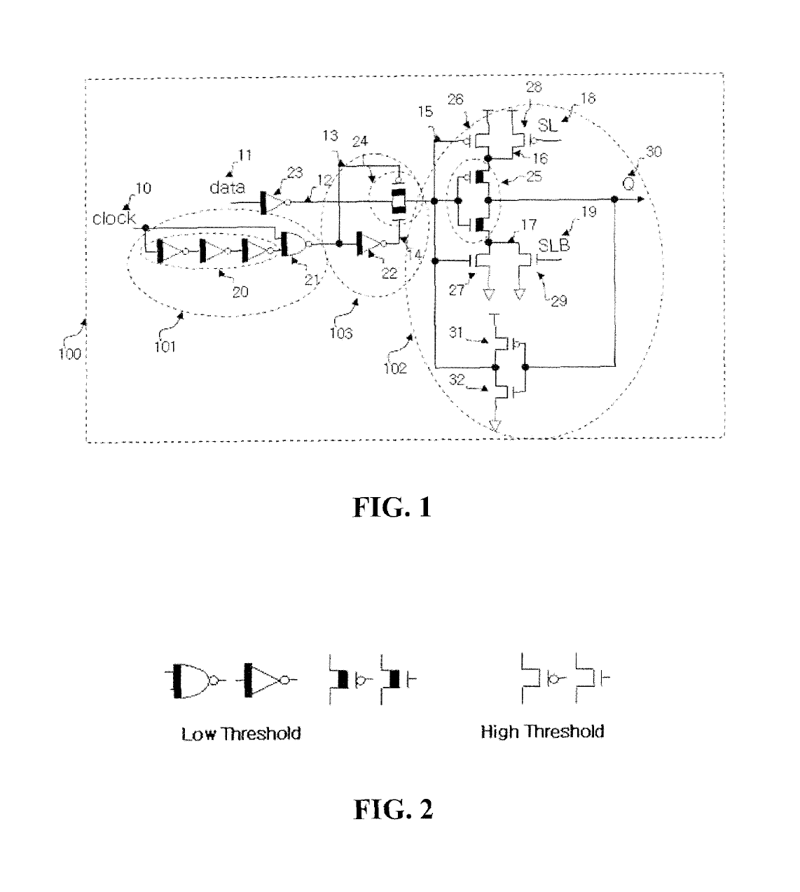

FIG. 1 is a circuit diagram of an MTCMOS flip-flop circuit according to a first embodiment.

As illustrated in FIG. 1, the MTCMOS flip-flop circuit 100 includes a clock signal generator 101 for generating clock control signals 13 and 14 for latching a data signal 11 at a rising time of a clock signal using an input clock 10.

The MTCMOS flip-flop circuit 100 can further include a data transmitting unit 103 for transmitting the input data signal 11 to a post stage, and a data latch and output unit 102 for storing a signal output from the data transmitting unit 103.

In the MTCMOS flip-flop circuit 100 according to the first embodiment, a pulsed clock is generated, an output is not floated in a sleep mode, and a high-speed operation is possible.

In a specific embodiment of the MTCMOS flip-flop circuit 100, a data input unit 23 includes an inverter for receiving an input data signal 11, inverting the input data signal 11, and outputting the inverted data signal to be an input of a switch 24 of the data transmitting unit 103.

The clock signal generator 101 can include a clock inverting delay unit 20 for receiving an input clock signal, and a logic gate 21 for generating pulsed clock 13 and 14 for latching the input data signal 11 at a rising time of the clock signal output from the clock inverting delay unit 20. Pulsed clock signal 14 can be the generated pulsed clock inverted through inverter 22.

The data transmitting unit 103 includes the switch 24 for receiving the pulsed clock 13 generated in the clock signal generator 101 to control transmission of data, receiving the inversed data output from the data input unit 23 and then selectively outputting inversed data to transmit the inversed data to the data latch and output unit 102 that is a post stage.

The data latch and output unit 102 can include a feedback inverter (31 and 32) having a feedback path (a feedback path including the feedback inverter 31 and 32) used for data latch so as to receive the inversed input data signal and generate an output signal Q 30 having the same phase as the data.

In one embodiment, the data latch and output unit 102 includes a configuration of transistors including: a first PMOS transistor 28 and a first NMOS transistor 29 each having a high threshold voltage at which they are activated in an active mode and are not activated in a sleep mode; a second PMOS transistor 26 and a second NMOS transistor 27 each having a high threshold voltage and a small size to maintain an active mode and drive a minimum current required in latching data; and a third PMOS transistor and a third NMOS transistor (combined as 25) each having a low threshold voltage for increasing a data transmission speed.

The data latch and output unit 102 can further include a PMOS transistor 31 and an NMOS transistor 32 each having a small size for receiving the output signal Q 30 and feeding the output signal Q 30 back to an inverter in the data latch unit for data latch so as to minimize a leakage current.

FIG. 2 is a view illustrating devices used in the MTCMOS flip-flop circuit according to the first embodiment as described above. The devices of FIG. 2 are also applied to a second embodiment which will be described later.

In particular, the devices include a PMOS transistor and a NMOS transistor having low and high thresholds. Descriptions of respective symbols are illustrated in FIG. 2.

Features of the low threshold MOS transistor and the high threshold MOS transistor will be briefly described for convenience of illustration. Specifically, a low threshold MOS transistor includes a small-sized device for implementing desired performance, but has a large leakage current. On the other hand, a high threshold MOS transistor includes a large-sized device for implementing desired performance, but has a small leakage current. In the present disclosure, such features are applied to the MTCMOS.

In the configuration of the MTCMOS flip-flop circuit of the first embodiment, the device having a low threshold may control active and sleep modes by removing a VDD connected to a general CMOS transistor device, replacing the VDD with a PMOS transistor having a high threshold and connecting a sleep signal to a gate. The device may control active and sleep modes by replacing a GND with an NMOS transistor. The two methods may be applied to the MTCMOS flip-flop circuit.

That is, in the clock signal generator 101, the clock inverting delay unit 20 of inverters having PMOS and NMOS transistors each having a low threshold voltage and the NAND gate 21 having at least one PMOS transistor and NMOS transistor with a low threshold voltage can be connected to drains of a PMOS and an NMOS transistor each having a high threshold voltage in place of a direct VDD or GND signal for the transistors with a low threshold voltage, and sources of the PMOS transistor and the NMOS transistor each having the high threshold voltage are respectively connected to the VDD and the GND.

Under the condition as described above, the operation of the MTCMOS flip-flop circuit of FIG. 1 will be described. For example, in an active mode, a sleep signal SL 18 has a logic low value, and an inverted sleep signal SLB 19 has a logic high value. Thus, the PMOS transistor 16 and the NMOS transistor 17 are always turned on.

At this time, in order to accelerate the operation of the circuit, a sufficiently large device is used such that a sufficient current can be applied to the PMOS transistor and the NMOS transistor in an inversion area 25 having a low threshold voltage, in which an actual inversion is performed.

According to an embodiment, the PMOS transistor 31 and the NMOS transistor 32 of the feedback inverter used for data latch function only to latch data. A small-sized device is used to minimize a leakage current in a sleep mode.

When the circuit is in the sleep mode, the PMOS transistor 16 and the NMOS transistor 17 for performance are turned off, and a latch state of data is maintained by the operations of the PMOS transistor 26 and the NMOS transistor 27 for the purpose of data retention.

Here, since only a minimum latch is maintained, the devices can have a small size. Consequently, a leakage current can be minimized in the sleep mode.

However, since the sizes of the PMOS transistor 26 and the NMOS transistor 27 are smaller than those of the PMOS transistor 16 and the NMOS transistor 17, the circuit is operated, but performance of the circuit is hardly enhanced.

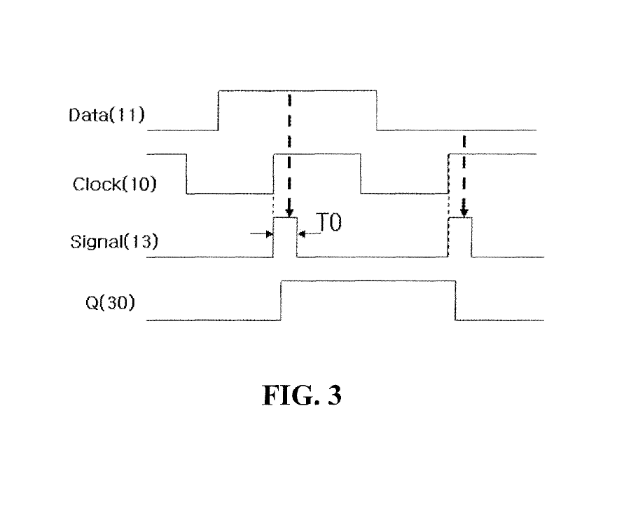

FIG. 3 is a signal diagram of the MTCMOS flip-flop circuit according to the first embodiment.

FIG. 3 illustrates a signal diagram of a clock and a data for illustrating a process in which a data 11 input in an active mode is latched by passing through the PMOS transistor and the NMOS transistor (switch 24) in the data transmitting unit 103 via the inverter 23.

If a clock 10 is toggled an inverted signal is generated by an inverter chain of the clock inverting delay unit 20 of FIG. 2. The inverted signal and the clock 10 are input to the NAND gate 21 to generate a pulsed clock signal 13 having a width T0. A signal 14 is generated by an inverter 22 in the data transmitting unit 103, and thus a transmission gate 24 including the PMOS transistor and the NMOS transistor is turned off. The data signal inverted by passing through the inverter 23 stands by at a node 12 and then passes through the transmission gate 24. Thus, data is latched due to the operation of the latch unit 102.

In the first embodiment, since the data is latched by passing through only the PMOS transistor and the NMOS transistor in the data transmitting unit 103, a fast speed of the flip-flop circuit can be implemented. Since small-sized devices are used, the flip-flop circuit can be implemented using a small area.

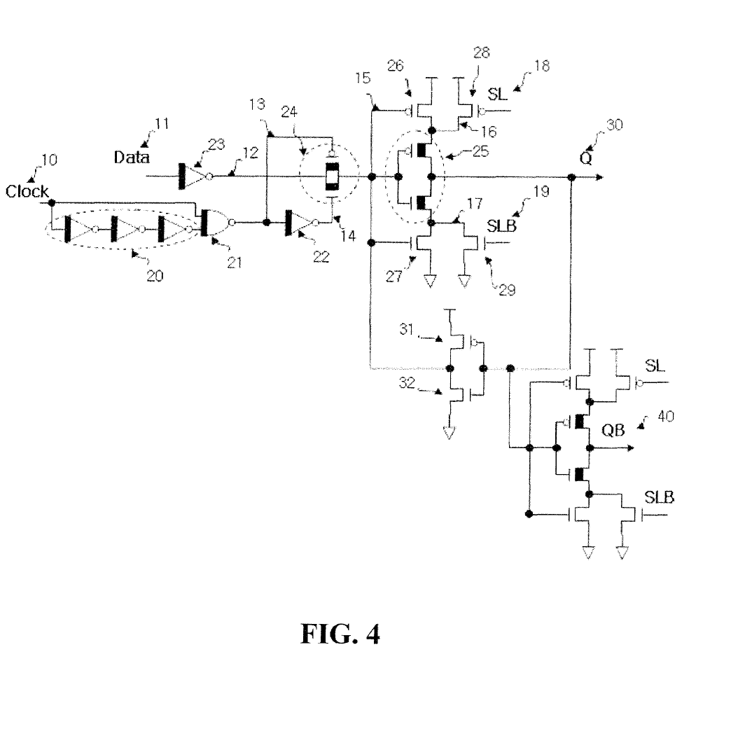

FIG. 4 is a circuit diagram of another example of the MTCMOS flip-flop circuit according to the first embodiment.

FIG. 4 illustrates a flip-flop circuit having output signals Q 30 and QB (Q Bar) 40 that are not floated in a sleep mode.

Here, the output signal QB 40 may also be generated using the same circuit as the circuit of FIG. 1 for generating the output signal Q 30 such that an output is prevented from being floated in a sleep mode. That is, the circuit may include an inverter having the same configuration as the inverter of FIG. 1 for generating the output signal Q. The output signal Q may be used as an input of an inverter for generating the QB.

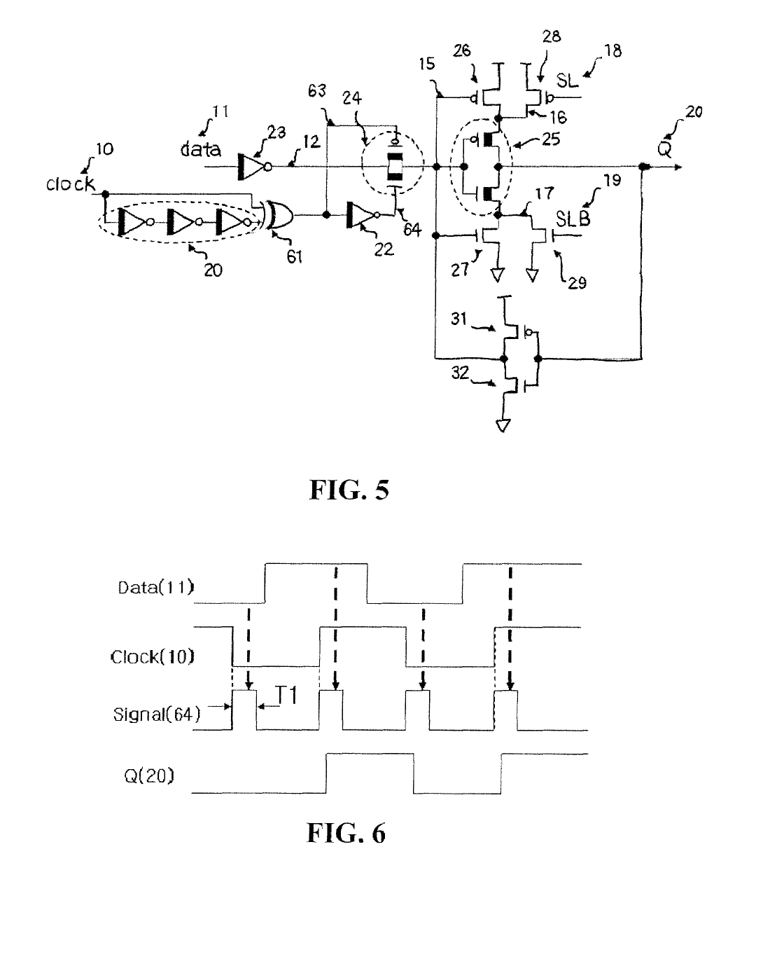

FIG. 5 is a circuit diagram of an MTCMOS flip-flop circuit according to a second embodiment.

In the MTCMOS flip-flop circuit according to the second embodiment, the NAND gate 21 for generating a pulsed clock in the MTMOS flip-flop circuit according the first embodiment is replaced with an Exclusive-OR gate 61.

FIG. 6 is a signal diagram of the MTCMOS flip-flop circuit according to the second embodiment.

According to the second embodiment, whenever an input clock signal 10 is toggled, a pulsed clock is generated. FIG. 5 illustrates such a circuit.

As illustrated in FIGS. 5 and 6, a pulsed clock 63 having a pulse width T1 and a pulsed clock 64 that is an inverted signal of the pulsed clock 63 allow a transmission gate including an NMOS transistor and a PMOS transistor (switch 24) to be turned on such that a data 11 is transmitted to a latch unit that is a post stage.

Accordingly, since the circuit of FIG. 5 can process a double amount of data at the same clock frequency, the circuit can be applied to various applications using a double data rate.

The MTCMOS flip-flop circuit according to the second embodiment may employ the configuration of the MTCMOS flip-flop circuit according to aspects of the first embodiment.

For example, the MTCMOS flip-flop circuit according to the second embodiment may employ the flip-flop circuit having the outputs Q 30 and QB 40 that are not floated in a sleep mode as illustrated in FIG. 4.

As described above, in an MTCMOS flip-flop circuit according to the present disclosure, since an output is not floated in a sleep mode, an additional node stabilization circuit is not required to inhibit a leakage current when the flip-flop in a sleep mode drives a CMOS or MTCMOS device in an active mode in an MTCMOS-CMOS design. A routing resource for routing is not used in such a circuit. Accordingly, the design can be simplified, and design time can be reduced.

Further, according to the present disclosure, when transmitting an input data signal to a latch unit, the input data signal passes through only a transmission gate. For this reason, a high-speed operation for generating an output signal Q from the input data signal can be implemented. In addition, a holding time and a set-up between data and clock signals can be minimized.

Furthermore, according to the present disclosure, since a NAND gate can be simply replaced with an Exclusive-OR gate, data can be caught at both rising and falling edges. Accordingly, a double data rate flip-flop can be implemented.

In addition, according to the present disclosure, when the flip-flop is in a sleep mode, a data holding path is formed by the operations of the devices having a minimum size for data latch. For this reason, a low leakage current can be implemented in the sleep mode.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A MTCOMS flip-flop circuit, comprising:
a data input unit comprising an inverter for receiving an input data signal, inverting the input data signal and then outputting an inverted data signal;
a clock signal generator comprising a clock inverting delay unit comprising at least one inverter for receiving an input clock signal, and a logic gate for generating a pulsed clock for latching the inverted data signal at a rising time of the input clock signal, wherein the logic gate receives as one input an output signal from the clock inverting delay unit;
a data transmitting unit comprising a switch for receiving the inverted data signal output from the data input unit to selectively output the inverted data signal, wherein the switch receives the pulsed clock output from the clock signal generator to control transmission of data; and
a data latch and output unit comprising a feedback inverter having a feedback path used for data latch so as to receive the inverted data signal output from the data transmitting unit and generate an output Q.

2. The MTCMOS flip-flop circuit according to claim 1, wherein the data latch and output unit further comprises a latch unit, comprising:
a first PMOS transistor and a first NMOS transistor each having a high threshold voltage at which the first PMOS transistor and the first NMOS transistor are activated in an active mode and are not activated in a sleep mode by receiving a sleep signal and an inverted sleep signal, respectively;
a second PMOS transistor and a second NMOS transistor each having a high threshold and a small size for maintaining an active mode and driving a minimum current required in latching data, wherein the second PMOS transistor and the second NMOS transistor receive the inverted data signal output from the data transmitting unit and the output of the feedback inverter; and
a third inverter comprising a third PMOS transistor and a third NMOS transistor each having a low threshold voltage for increasing a data transmission speed, wherein the third PMOS transistor and the third NMOS transistor receive the inverted data signal output from the data transmitting unit and the output of the feedback inverter, and wherein the source of the third PMOS transistor is connected to the drains of both the first and second PMOS transistors and the source of the third NMOS transistor is connected to the drains of both the first and second NMOS transistors.

3. The MTCMOS flip-flop circuit according to claim 2, wherein the feedback inverter of the data latch and output unit comprises a fourth PMOS transistor and a fourth NMOS transistor each having a small size to minimize a leakage current while receiving the output signal of the third inverter to perform data latch.

4. The MTCMOS flip-flop circuit according to claim 1, wherein the at least one inverter of the clock inverting delay unit of the clock signal generator comprises a PMOS transistor and an NMOS transistor each having a low threshold voltage for inverting and delaying the input clock signal.

5. The MTCMOS flip-flop circuit according to claim 1, wherein the logic gate of the clock signal generator comprises a NAND gate having two inputs, wherein the NAND gate utilizes PMOS and NMOS transistors each having a low threshold voltage for generating the pulsed clock.

6. The MTCMOS flip-flop circuit according to claim 1, wherein the data transmitting unit further comprises a second inverter utilizing transistors having a low threshold voltage for inverting the generated pulsed clock output from the clock signal generator.

7. The MTCMOS flip-flop circuit according to claim 1, wherein the data latch and output unit provides output signals Q and QB that are not floated in a sleep mode where QB represents an inverted signal of Q.

8. The MTCMOS flip-flop circuit according to claim 7, further comprising a predetermined inverter for generating the output signal QB wherein the output signal Q is an input signal of the predetermined inverter for generating the output signal QB.

9. The MTCMOS flip-flop circuit according to claim 8, wherein the predetermined inverter comprises:
a first PMOS transistor and a first NMOS transistor each having a high threshold voltage at which the first PMOS transistor and the first NMOS transistor are activated in an active mode and are not activated in a sleep mode by receiving a sleep signal and an inverted sleep signal, respectively;
a second PMOS transistor and a second NMOS transistor each having a high threshold and a small size for maintaining an active mode and driving a minimum current required in latching data, wherein the second PMOS transistor and the second NMOS transistor receive as input the output signal Q; and
a third inverter comprising a third PMOS transistor and a third NMOS transistor each having a low threshold voltage for increasing a data transmission speed, wherein the third PMOS transistor and the third NMOS transistor receive as input the output signal Q, and wherein the source of the third PMOS transistor is connected to the drains of both the first and second PMOS transistors and the source of the third NMOS transistor is connected to the drains of both the first and second NMOS transistors.

10. A MTCMOS flip-flop circuit, comprising:
a data input unit comprising an inverter for receiving an input data signal, inverting the input data signal and then outputting an inverted data signal;
a clock signal generator comprising a clock inverting delay unit comprising at least one inverter for receiving an input clock signal, and a logic gate for generating a pulsed clock for latching the inverted data signal at both a rising time and falling time of the input clock signal, wherein the logic gate receives as one input an output signal from the clock inverting delay unit;
a data transmitting unit comprising a switch for receiving the inverted data signal output from the data input unit to selectively output the inverted data signal, wherein the switch receives the pulsed clock output from the clock signal generator to control transmission of data; and
a data latch and output unit comprising a feedback inverter having a feedback path used for data latch so as to receive the inverted data signal output from the data transmitting unit and generate an output Q.

11. The MTCMOS flip-flop circuit according to claim 10, wherein the logic gate utilizes a pulsed clock at every transition of the input clock signal, thereby implementing a double data rate.

12. The MTCMOS flip-flop circuit according to claim 10, wherein the logic gate of the clock signal generator comprises a XOR gate having two inputs, wherein the XOR gate utilizes PMOS and NMOS transistors each having a low threshold voltage for generating the pulsed clock.

13. The MTCMOS flip-flop circuit according to claim 10, wherein the data latch and output unit further comprises a latch unit, comprising:
a first PMOS transistor and a first NMOS transistor each having a high threshold voltage at which the first PMOS transistor and the first NMOS transistor are activated in an active mode and are not activated in a sleep mode by receiving a sleep signal and an inverted sleep signal, respectively;
a second PMOS transistor and a second NMOS transistor each having a high threshold and a small size for maintaining an active mode and driving a minimum current required in latching data, wherein the second PMOS transistor and the second NMOS transistor receive the inverted data signal output from the data transmitting unit and the output of the feedback inverter; and
a third inverter comprising a third PMOS transistor and a third NMOS transistor each having a low threshold voltage for increasing a data transmission speed, wherein the third PMOS transistor and the third NMOS transistor receive the inverted data signal output from the data transmitting unit and the output of the feedback inverter, and wherein the source of the third PMOS transistor is connected to the drains of both the first and second PMOS transistors and the source of the third NMOS transistor is connected to the drains of both the first and second NMOS transistors.

14. The MTCMOS flip-flop circuit according to claim 13, wherein the feedback inverter of the data latch and output unit comprises a fourth PMOS transistor and a fourth NMOS transistor each having a small size to minimize a leakage current while receiving the output signal of the third inverter to perform data latch.

15. The MTCMOS flip-flop circuit according to claim 10, wherein the at least one inverter of the clock inverting delay unit of the clock signal generator comprises a PMOS transistor and an NMOS transistor each having a low threshold voltage for inverting and delaying the input clock signal.

16. The MTCMOS flip-flop circuit according to claim 10, wherein the data transmitting unit further comprises a second inverter utilizing transistors having a low threshold voltage for inverting the generated pulsed clock output from the clock signal generator.

17. The MTCMOS flip-flop circuit according to claim 10, wherein the data latch and output unit provides output signals Q and QB that are not floated in a sleep mode where QB represents an inverted signal of Q.

18. The MTCMOS flip-flop circuit according to claim 10, further comprising a predetermined inverter for generating the output signal QB wherein the output signal Q is an input signal of the predetermined inverter for generating the output signal QB.

19. The MTCMOS flip-flop circuit according to claim 18, wherein the predetermined inverter comprises:
a first PMOS transistor and a first NMOS transistor each having a high threshold voltage at which the first PMOS transistor and the first NMOS transistor are activated in an active mode and are not activated in a sleep mode by receiving a sleep signal and an inverted sleep signal, respectively;
a second PMOS transistor and a second NMOS transistor each having a high threshold and a small size for maintaining an active mode and driving a minimum current required in latching data, wherein the second PMOS transistor and the second NMOS transistor receive as input the output signal Q; and
a third inverter comprising a third PMOS transistor and a third NMOS transistor each having a low threshold voltage for increasing a data transmission speed, wherein the third PMOS transistor and the third NMOS transistor receive as input the output signal Q, and wherein the source of the third PMOS transistor is connected to the drains of both the first and second PMOS transistors and the source of the third NMOS transistor is connected to the drains of both the first and second NMOS transistors.
